(19) United States
(12) Patent Application Publication
(10) Pub. No.: US 2018/0053740 A1
(43) Pub. Date: Feb. 22, 2018

(54) LAND GRID BASED MULTI SIZE PAD PACKAGE

(71) Applicant: QUALCOMM Incorporated, San Diego, CA (US)

(72) Inventors: Manoj KAKADE, San Diego, CA (US); Haiyong XU, San Diego, CA (US); Ruey Kae ZANG, San Diego, CA (US); Yue LI, San Diego, CA (US); Xiaonan ZHANG, San Diego, CA (US); Christine HAU-RIEGE, Fremont, CA (US)

(21) Appl. No.: 15/243,923

(22) Filed: Aug. 22, 2016

(51) Int. Cl. H01L 23/00

(52) U.S. Cl. CPC H01L 24/14; H01L 2924/1206; H01L 24/05; H01L 24/13; H01L 24/94; H01L 2224/02373; H01L 2224/02379; H01L 2224/0239; H01L 2224/024; H01L 2924/01029; H01L 2924/07025; H01L 2224/0401; H01L 2224/05024; H01L 2224/05124; H01L 2224/13026; H01L 2224/13147; H01L 2924/014; H01L 2224/1403; H01L 2224/06138; H01L 2924/15313; H01L 24/02

(57) ABSTRACT

The present disclosure provides packages and methods for fabricating packages. A package may comprise a wafer-level package (WLP) layer comprising first and second WLP contacts and first and second conductive pillars disposed on the first and second WLP contacts. Each conductive pillar may comprise a surface opposite the WLP contact that forms an array pad. The array pads may have different sizes. The package may further comprise a mold over the WLP layer and at least partially surrounding the conductive pillars, wherein the mold compound and the first array pads form a substantially planar LGA contact surface that is configured to couple the package to a land grid array.

Aspects of this disclosure relate generally to integrated circuit devices, and more particularly to wafer-level packages (WLP) having array pads arranged in a land grid array (LGA).

Conventional WLPs may be mounted to a surface of a printed circuit board (PCB) to form an integrated circuit (IC) package. The WLP may include, for example, a microprocessor. The WLP may include a plurality of WLP contacts arranged in an array. The PCB may include a plurality of PCB contacts that complement the respective positions of the WLP contacts. Solder balls may be applied to, for example, the WLP contacts and the solder balls may be disposed against the complementary PCB contacts. After the solder balls harden, the WLP may be mounted to the PCB to form the integrated circuit package.

In conventional WLPs, there may be a maximum current flowing through each solder ball. In some implementations, the maximum current may cause a current bottleneck for current flowing to/from the WLP. Moreover, the solder balls may cause high levels of capacitive coupling. Accordingly, the solder balls must be placed a certain distance apart. The solder balls may also increase the height of the integrated circuit package and reduce heat transfer from the WLP to the PCB.

Accordingly, new arrangements and methods for coupling WLPs to PCBs are needed.

### SUMMARY

The following summary is an overview provided solely to aid in the description of various aspects of the disclosure and is provided solely for illustration of the aspects and not limitation thereof.

In one aspect, the present disclosure provides a package. The package may comprise a wafer-level package (WLP) layer comprising a first WLP contact and a second WLP contact, a first conductive pillar disposed on the first WLP contact, the first conductive pillar comprising a surface opposite the first WLP contact that forms a first array pad, a second conductive pillar disposed on the second WLP contact, the second conductive pillar comprising a surface opposite the second WLP contact that forms a second array pad, wherein the second array pad has a different size than the first array pad, and a mold over the WLP layer and at least partially surrounding the first conductive pillar and the second conductive pillar, wherein the mold compound, the first array pad, and the second array pad form a substantially planar land grid array contact surface that is configured to couple the package to a land grid array.

In another aspect, the present disclosure provides a method of fabricating a package. The method may comprise providing a wafer-level package (WLP) layer comprising a first WLP contact and a second WLP contact, disposing a first conductive pillar on the first WLP contact, the first conductive pillar comprising a surface opposite the first WLP contact that forms a first array pad, disposing a second conductive pillar on the second WLP contact, the second conductive pillar comprising a surface opposite the second WLP contact that forms a second array pad, wherein the second array pad has a different size than the first array pad, disposing a mold over the WLP layer that at least partially surrounds the first conductive pillar and the second conductive pillar, and removing at least a portion of the mold, at least a portion of the first conductive pillar, at least a portion of the second conductive pillar, or any combination thereof, such that the mold compound, the first array pad, and the second array pad form a substantially planar land grid array contact surface that is configured to couple the package to a land grid array.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the invention, and in which:

FIG. 1 generally illustrates a conventional BGA arrangement for a wafer-level package.

FIG. 2 generally illustrates a conventional BGA arrangement for a fan-out wafer-level package.

FIG. 3 generally illustrates a LGA arrangement for a wafer-level package in accordance with aspects of the disclosure.

FIG. 4 generally illustrates a LGA arrangement for a fan-out wafer-level package in accordance with aspects of the disclosure.

FIG. 5 generally illustrates a comparison between a conventional BGA arrangement and an LGA arrangement in accordance with aspects of the disclosure.

FIG. 6 generally illustrates an LGA arrangement in accordance with aspects of the disclosure.

FIG. 7 generally illustrates another comparison between a conventional BGA arrangement and an LGA arrangement in accordance with aspects of the disclosure.

FIG. 8 generally illustrates a method for fabricating, in accordance with aspects of the disclosure, a mountable multi-size pad wafer-level package.

FIG. 9A generally illustrates a mountable multi-size pad wafer-level package in a first stage of fabrication in accordance with aspects of the disclosure.

FIG. 9B generally illustrates the mountable multi-size pad wafer-level package of FIG. 9A in a second stage of fabrication.

FIG. 9C generally illustrates the mountable multi-size pad wafer-level package of FIG. 9A in a third stage of fabrication.

FIG. 9D generally illustrates the mountable multi-size pad wafer-level package of FIG. 9A in a fourth stage of fabrication.

FIG. 9E generally illustrates the mountable multi-size pad wafer-level package of FIG. 9A in a fifth stage of fabrication.

FIG. 9F generally illustrates the mountable multi-size pad wafer-level package of FIG. 9A in an optional sixth stage of fabrication.

FIG. 10 generally illustrates a block diagram showing an exemplary wireless communication system in which aspects of the disclosure may be advantageously employed.

FIG. 11 generally illustrates a block diagram illustrating a design workstation used for circuit, layout, and logic design of the disclosed semiconductor IC package.

FIG. 12 generally illustrates a conventional BGA arrangement for an integrated circuit package.

FIG. 13 generally illustrates an LGA arrangement for an integrated circuit package in accordance with aspects of the disclosure.

### DETAILED DESCRIPTION

Aspects of the disclosure are disclosed in the following description and related drawings directed to specific aspects of the disclosure. Alternate aspects may be devised without departing from the scope of the invention. Additionally, well-known elements of the invention will not be described in detail or will be omitted so as not to obscure the relevant details of the invention.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the invention” does not require that all aspects of the invention include the discussed feature, advantage or mode of operation.

As used herein, the term “vertical” is generally defined with respect to a surface of a substrate or carrier upon which a semiconductor package is formed. The substrate or carrier will generally define a “horizontal” plane, and a vertical direction approximates a direction that is roughly orthogonal to the horizontal plane.

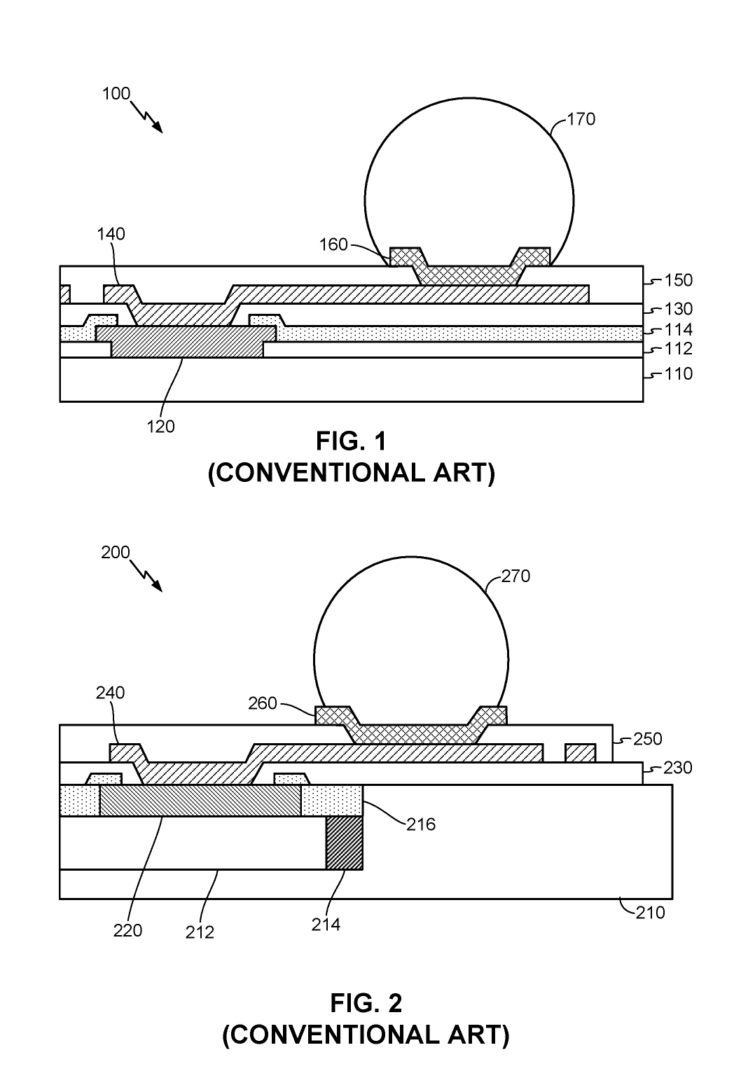

FIGS. 1-2 generally illustrate conventional arrangements for disposing wafer-level packages (WLPs) on a printed circuit board (PCB) using a ball grid array (BGA). As used herein, the term “wafer-level package” may refer to a wafer-level package (for example, the wafer-level package 100 depicted in FIG. 1) and/or a fan-out wafer-level package (for example, the fan-out wafer-level package 200 depicted in FIG. 2).

FIG. 1 generally illustrates a conventional BGA arrangement for a wafer-level package 100. The wafer-level package 100 may include a semiconductor 110, a first passivation layer 112 disposed at least in part on the semiconductor 110, a second passivation layer 114 disposed at least in part on the first passivation layer 112, a first polymer layer 130 disposed at least in part on the second passivation layer 114, and a pad 120 disposed at least in part on the semiconductor 110.

The wafer-level package 100 may further include a redistribution layer 140 disposed at least in part on the first polymer layer 130, and a second polymer layer 150 disposed at least in part on the redistribution layer 140.

The wafer-level package 100 may further include a UBM 160 (where UBM refers to “under-bump metallization”) disposed at least in part on the redistribution layer 140 and a solder ball 170 disposed at least in part on the UBM 160. The solder ball 170 may be in contact with the UBM 160, which may be in contact with the redistribution layer 140, which may be in contact with the pad 120, which may be in contact with one or more components of the semiconductor 110. Accordingly, current may flow freely between the semiconductor 110 and the solder ball 170.

FIG. 2 generally illustrates a conventional BGA arrangement for a fan-out wafer-level package 200. The fan-out wafer-level package 200 may include a fan-out area 210, a silicon layer 212 disposed at least in part on the fan-out area 210, a seal ring 214 disposed around the silicon layer 212, a passivation layer 216 disposed at least in part on the silicon layer 212, a pad 220 disposed at least in part on the silicon layer 212, and a first polymer layer 230 disposed at least in part on one or more of the passivation layer 216 and the fan-out area 210.

The fan-out wafer-level package 200 may further include a redistribution layer 240 disposed at least in part on the first polymer layer 230, and a second polymer layer 250 disposed at least in part on the redistribution layer 240.

The fan-out wafer-level package 200 may further include a UBM 260 (where UBM refers to “under-bump metallization”) disposed at least in part on the redistribution layer 240 and a solder ball 270 disposed at least in part on the UBM 260. The solder ball 270 may be in contact with the UBM 260, which may be in contact with the redistribution layer 240, which may be in contact with the pad 220, which may be in contact with one or more components of the silicon layer 212 and/or the fan-out area 210. Accordingly, current may flow freely between the solder ball 270 and one or more of the silicon layer 212 and the fan-out area 210.

Although the solder balls 170, 270 depicted in FIGS. 1-2 are solitary, it will be understood that a plurality of solder balls 170, 270 may be disposed on a plurality of UBMs 160, 260. The solder balls 170, 270 may be disposed on the wafer-level packages 100, 200 so as to complement one or more PCB contacts on a printed circuit board (PCB). Accordingly, the wafer-level packages 100, 200 may be disposed on a PCB such that the solder balls 170, 270 are coupled to the PCB contacts. After the solder balls 170, 270 harden, the wafer-level packages 100, 200 may be mounted to the PCB to form the integrated circuit package.

In conventional BGA arrangements such as those depicted in FIGS. 1-2, there may be a maximum current flowing through any particular one of the solder balls 170, 270. In some implementations, the maximum current may cause a current bottleneck for current flowing to/from the wafer-level packages 100, 200. Moreover, the solder balls 170, 270 may cause high levels of capacitive coupling. Accordingly, the solder balls 170, 270 must be placed a certain distance apart. The solder balls 170, 270 may also increase the height of the integrated circuit package and reduce heat transfer from the wafer-level packages 100, 200 to the PCB.

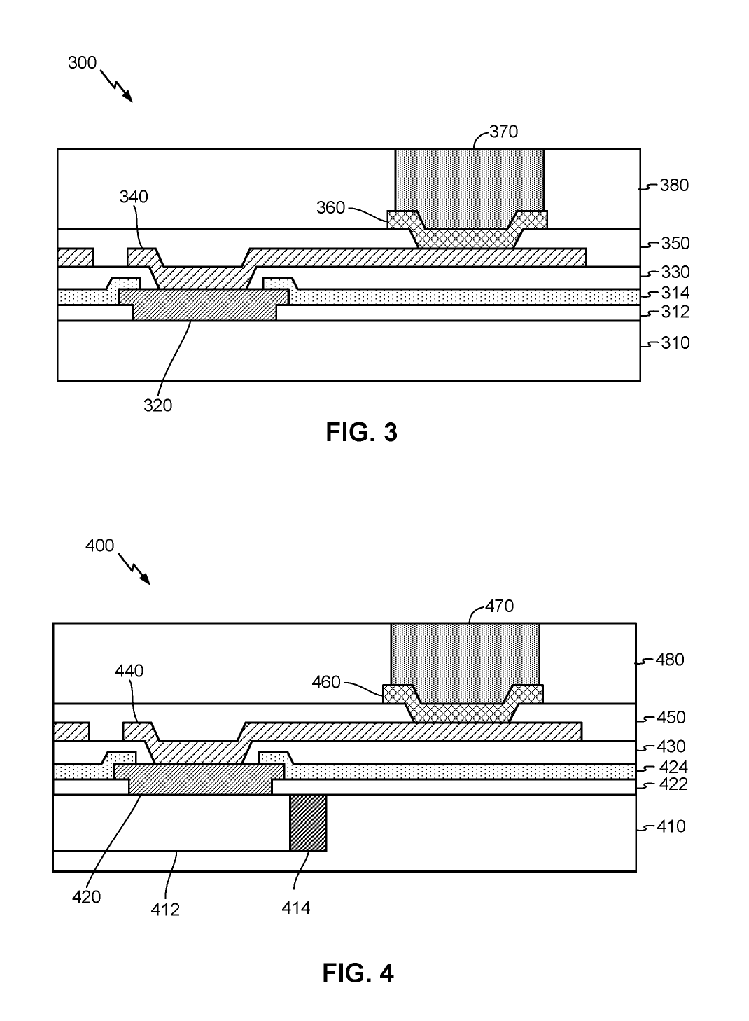

FIGS. 3-4 generally illustrate arrangements for disposing wafer-level packages (WLPs) on a printed circuit board (PCB) using a land grid array (LGA) in accordance with aspects of the disclosure.

FIG. 3 generally illustrates a LGA arrangement for a package 300. The package 300 may be a wafer-level package (WLP). The package 300 may be a means for processing. The package 300 may include a semiconductor 310, a first passivation layer 312 disposed at least in part on the semiconductor 310, a second passivation layer 314 disposed at least in part on the first passivation layer 312, a first polymer layer 330 disposed at least in part on the second passivation layer 314, and a pad 320 disposed at least in part on the semiconductor 310. The semiconductor 310 may include silicon. The pad 320 may be an aluminum pad.

The package 300 may further include a redistribution layer 340 (where redistribution layer may be abbreviated “RDL”) disposed at least in part on the first polymer layer 330, and a second polymer layer 350 disposed at least in part on the redistribution layer 340. The pad 320 and the redistribution layer 340 may include a conductive trace. The redistribution layer 340 may include a copper parallel process interposer (“PPI”). The aforementioned elements 310, 312, 314, 320, 330, 340, 350, or any combination thereof, may be referred to as a WLP layer. The polymer layers 330, 350 may include polyimide.

The package 300 may optionally include a UBM 360 (where UBM refers to “under-bump metallization”) disposed at least in part on at least a portion of the WLP layer, for example, the redistribution layer 340. The package 300 may further include a conductive pillar 370 disposed at least in part on the UBM 360. The conductive pillar 370 may be in contact with the UBM 360, which may be in contact with the redistribution layer 340, which may be in contact with the pad 320, which may be in contact with one or more components of the semiconductor 310. The UBM 360 may be referred to as a WLP contact. Alternatively, the UBM 360 may be omitted and the conductive pillar 370 may be disposed directly on at least a portion of the redistribution layer 340. The portion of the redistribution layer 340 upon which the conductive pillar 370 is disposed may also be referred to as a WLP contact. The conductive pillar 370 may have a surface opposite the WLP contact (for example, the UBM 360 depicted in FIG. 3). The surface opposite the WLP contact may form an array pad. A plurality of array pads analogous to the array pad associated with the conductive pillar 370 may form an LGA contact surface and may be further configured to couple the package 300 to a land grid array. The WLP contact, for example, the UBM 360 and/or the portion of the redistribution layer 340 upon which the conductive pillar 370 is disposed, may be a means for contacting. The conductive pillar 370 may be a means for conducting.

The package 300 may further include a mold 380 disposed at least in part on the second polymer layer 350. The mold 380 may surround the conductive pillar 370 and may also provide mechanical support for the conductive pillar 370. The mold 380 may be a means for supporting. The array pad associated with the conductive pillar 370 may be a substantially planar surface. The top surface of the mold 380 may also be substantially planar. The substantially planar top surfaces of the conductive pillar 370 and the mold 380, respectively, may share a common plane and may form an LGA contact surface. The mold 380 may include mold compound.

FIG. 4 generally illustrates a LGA arrangement for a package 400. The package 400 may be a fan-out WLP. The package 400 may be a means for processing. The package 400 may include a fan-out area 410, a semiconductor 412 disposed at least in part on the fan-out area 410, a seal ring 414 disposed around the semiconductor 412, a pad 420 disposed at least in part on the semiconductor 412, and a first polymer layer 430. The package 400 may further include a first passivation layer 422 disposed at least in part on the fan-out area 410 and/or the semiconductor 412, a second passivation layer 424 disposed at least in part on the first passivation layer 422, a first polymer layer 430 disposed at least in part on the second passivation layer 424, and a pad 420 disposed at least in part on the semiconductor 412. The semiconductor 412 may include silicon. The pad 420 may be an aluminum pad.

The package 400 may further include an redistribution layer 440 (where redistribution layer may be abbreviated “RDL”) disposed at least in part on the first polymer layer 430, and a second polymer layer 450 disposed at least in part on the redistribution layer 440. The pad 420 and the redistribution layer 440 may include a conductive trace. The redistribution layer 440 may include a copper parallel process interposer (“PPI”). The aforementioned elements 410, 412, 414, 420, 422, 424, 430, 440, 450, or any combination thereof, may be referred to as a WLP layer. The polymer layers 430, 450 may include polyimide.

The package 400 may optionally include a UBM 460 (where UBM refers to “under-bump metallization”) disposed at least in part on at least a portion of the WLP layer, for example, the redistribution layer 440. The package 400 may further include a conductive pillar 470 disposed at least in part on the UBM 460. The conductive pillar 470 may be in contact with the UBM 460, which may be in contact with the redistribution layer 440, which may be in contact with the pad 420, which may be in contact with one or more components of the semiconductor 412 and/or the fan-out area 410. The UBM 460 may be referred to as a WLP contact. Alternatively, the UBM 460 may be omitted and the conductive pillar 470 may be disposed directly on at least a portion of the redistribution layer 440. The portion of the redistribution layer 440 upon which the conductive pillar 470 is disposed may also be referred to as a WLP contact. The conductive pillar 470 may have a surface opposite the WLP contact (for example, the UBM 460 depicted in FIG. 4). The surface opposite the WLP contact may form an array pad. A plurality of array pads analogous to the array pad associated with the conductive pillar 470 may form an LGA contact surface and may be further configured to couple the package 400 to a land grid array. The WLP contact, for example, the UBM 460 and/or the portion of the redistribution layer 440 upon which the conductive pillar 470 is disposed, may be a means for contacting. The conductive pillar 470 may be a means for conducting.

The package 400 may further include a mold 480 disposed at least in part on the second polymer layer 450. The mold 480 may surround the conductive pillar 470 and may also provide mechanical support for the conductive pillar 470. The mold 480 may be a means for supporting. The array pad associated with the conductive pillar 470 may be a substantially planar surface. The top surface of the mold 480 may also be substantially planar. The substantially planar top surfaces of the conductive pillar 470 and the mold 480, respectively, may share a common plane and may form an LGA contact surface. The mold 480 may include mold compound.

Although the conductive pillars 370, 470 depicted in FIGS. 3-4 are solitary, it will be understood that a plurality of conductive pillars 370, 470 may be disposed on a plurality of UBMs 360, 460 and/or a plurality of portions of the redistribution layers 340, 440. The conductive pillars 370, 470 may be disposed on the packages 300, 400 so as to complement one or more PCB contacts on a printed circuit board (PCB). In particular, the positions of the respective array pads associated with the conductive pillars 370, 470 may mirror the positions of the one or more PCB contacts. Accordingly, the packages 300, 400 may be disposed on a PCB such that the conductive pillars 370, 470 are coupled to the PCB contacts. The PCB contacts may be arranged in a land grid array. Accordingly, the mold compound and the respective array pads may form a substantially planar land grid array contact surface that is configured to couple the package to a land grid array.

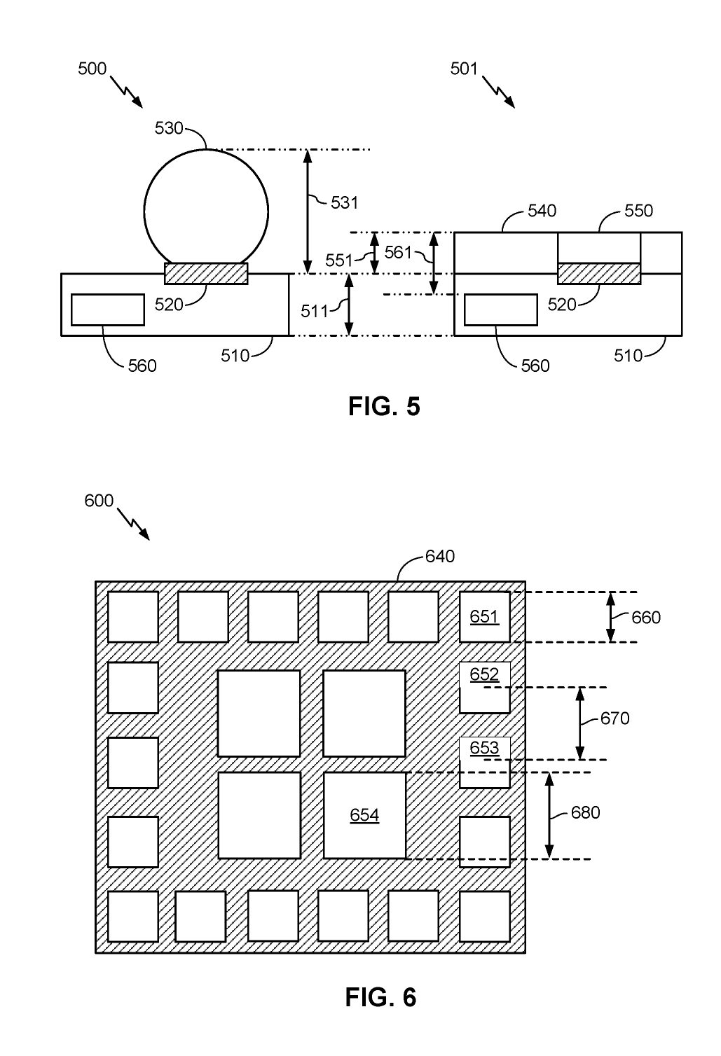

The arrangements shown in FIGS. 3-4 (having conductive pillars 370, 470) may exhibit one or more advantages relative to the arrangements shown in FIGS. 1-2 (having solder balls 170, 270). The advantages may include one or more of the advantages described in greater detail below with respect to FIGS. 5-7.

FIG. 5 generally illustrates a WLP arrangement 500 having a conventional BGA arrangement and a WLP arrangement 501 having (in accordance with aspects of the disclosure) an LGA arrangement. The WLP arrangement 500 may be analogous in some respects to the wafer-level packages 100, 200 depicted in FIGS. 1-2, whereas the WLP arrangement 501 may be analogous in some respects to the packages 300, 400 depicted in FIGS. 3-4.

The WLP arrangement 500 and the WLP arrangement 501 may have some components in common. For example, each of the WLP arrangements 500, 501 may include a WLP layer 510 and a UBM 520. It will be understood that the WLP layer 510 may include one or more components and/or layers analogous to those depicted in FIGS. 1-4. The WLP layer 510 may be a means for processing and the UBM 520 may be a means for contacting. The WLP arrangement 500 includes a solder ball 530 similar to the solder balls 170, 270 depicted in FIGS. 1-2, whereas the WLP arrangement 501 includes a mold 540 and a conductive pillar 550 similar to the molds 380, 480 and conductive pillars 370, 470 depicted in FIGS. 3-4. The mold 540 may be a means for supporting and the conductive pillar 550 may be a means for conducting.

The WLP layer 510 may be mounted to a PCB (not shown) to form an integrated circuit package. Both the WLP layer 510 and the PCB may have a substantially ‘flat’ shape. A component with a flat shape may have a component length and a component width that greatly exceed the component height, for example, the component length and a component width may be ten times, one hundred times, or one thousand times the component height.

In some implementations, it may be advantageous to minimize the overall height of the integrated circuit package. After the WLP layer 510 is mounted to the PCB, the overall height of the integrated circuit package may depend on the height of the WLP layer 510, the height of the PCB, and the height of the components used to mount the WLP layer 510 to the PCB.

As will be understood from FIG. 5, one way to advantageously minimize the overall height of the integrated circuit package is to minimize the height of the components used to mount the WLP layer 510 to the PCB. The WLP layer 510 depicted in FIG. 5 may have a WLP height 511. As will be understood from FIG. 5, the WLP arrangement 500 may be associated with a BGA component height 531 attributable to the height of the solder ball 530, whereas the WLP arrangement 501 may be associated with a LGA component height 551 attributable to the height of the mold 540 and the conductive pillar 550. As an example, the BGA component height 531 may be equal to or on the order of 180 μm, whereas the LGA component height 551 may be much smaller, for example, 25 μm. Accordingly, the overall height of the integrated circuit package may be reduced by over one hundred micrometers.

Another advantage of the WLP arrangement 501 is the flexibility with which the LGA component height 551 may be selected. For example, in some implementations, the WLP layer 510 may include a component 560 associated with a keepout area or keepout zone. The component 560 may be associated with electrical and/or magnetic fields (for example, an inductor) that must be displaced from the PCB by at least a keepout distance 561. As can be understood from FIG. 5, the LGA component height 551 of the mold 540 and the conductive pillar 550 may be selected such that the component 560 is displaced from the PCB by at least the keepout distance 561. Accordingly, as the position or characteristics of the component 560 changes (as may occur during circuit design), the LGA component height 551 may be flexibly selected such that the keepout distance 561 is observed but the LGA component height 551 (and the overall height of the integrated circuit package) is otherwise minimized

FIG. 6 generally illustrates an LGA arrangement 600 in accordance with aspects of the disclosure. The LGA arrangement 600 may be analogous in some respects to the packages 300, 400 depicted in FIGS. 3-4 and/or the WLP arrangement 501 depicted in FIG. 5.

The LGA arrangement 600 may include a mold 640 analogous to the molds 380, 480, 540 depicted in FIGS. 3-5. The LGA arrangement 600 may further include a plurality of array pads including a first array pad 651, a second array pad 652, a third array pad 653, and a fourth array pad 654. As used herein, the term “array pad” may refer to an external surface of a conductive pillar analogous to the conductive pillars 370, 470, 550 depicted in FIGS. 3-5. Each of the array pads 651, 652, 653, 654 may be substantially planar and each of the plurality of array pads 651, 652, 653, 654 may share a plane with one or more other array pads and/or an external surface of the mold 640. The conductive pillars upon which the array pads 651, 652, 653, 654 are respectively disposed may themselves be disposed on at least one WLP contact (as described previously in FIGS. 3-4). Therefore, the array pads 651, 652, 653, 654 may conduct current to and from the WLP contacts. The array pads 651, 652, 653, 654 may be disposed in accordance with the LGA arrangement 600, which may be designed to complement electrical contacts of a PCB.

The plurality of array pads including array pads 651, 652, 653, 654 may have flexible dimensions and spacings. As will be understood from FIG. 6, the first array pad 651 may have a dimension 660, for example, a length or width. The second array pad 652 and third array pad 653 may have a spacing 670, for example, a distance between respective centers of the second array pad 652 and third array pad 653. The fourth array pad 654 may have a dimension 680, for example, a length or width. Because of the flexible dimensions and spacing of the LGA arrangement 600, the dimension 660, spacing 670, and dimension 680 may be flexibly selected in accordance with design considerations.

For example, the dimension 660 (and/or a similar dimension associated with one or more additional array pads) may be reduced in order to advantageously minimize the overall length or width of the LGA arrangement 600. Additionally or alternatively, the spacing 670 (and/or a similar spacing associated with two or more additional array pads) may be reduced in order to advantageously minimize the overall length or width of the LGA arrangement 600. Additionally or alternatively, the spacing 670 (and/or a similar spacing associated with two or more additional array pads) may be optimized by determining a minimum spacing in order to advantageously reduce capacitive coupling between adjacent array pads. Additionally or alternatively, the dimension 680 (and/or a similar spacing associated with two or more additional array pads) may be increased in order to advantageously optimize the maximum current from the WLP to the PCB or vice-versa, or to advantageously optimize the heat transfer from the WLP to the PCB or vice-versa.

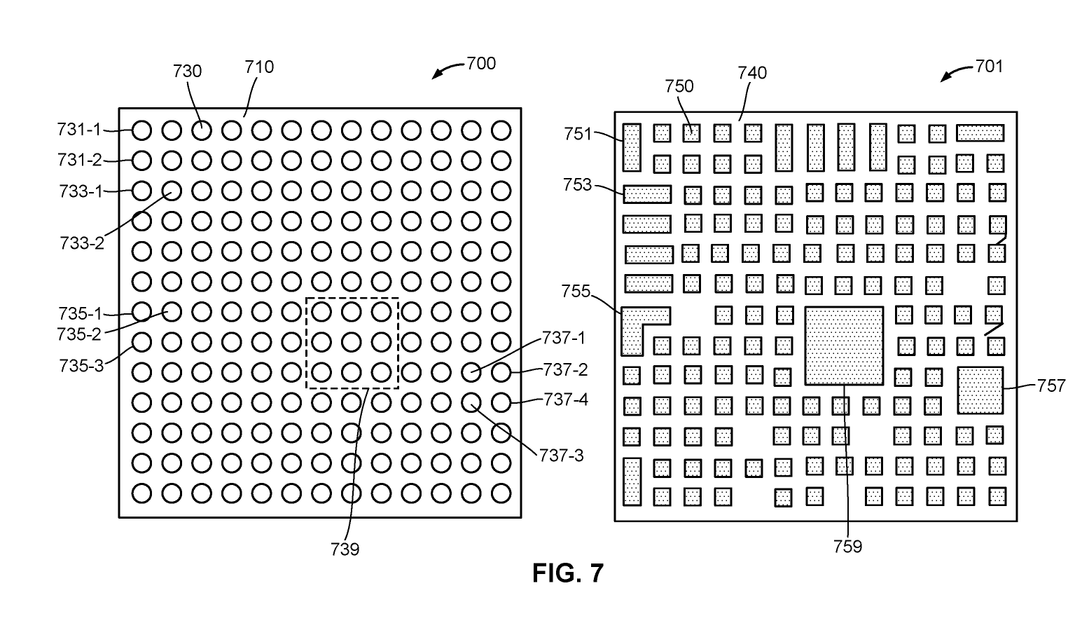

FIG. 7 generally illustrates a conventional BGA arrangement 700 and a multi-size pad LGA arrangement 701 in accordance with aspects of the disclosure. The BGA arrangement 700 may be analogous in some respects to the wafer-level packages 100, 200 depicted in FIGS. 1-2 and/or the WLP arrangement 500 depicted in FIG. 5, whereas the LGA arrangement 701 may be analogous in some respects to the packages 300, 400 depicted in FIGS. 3-4 and/or the WLP arrangement 501 depicted in FIG. 5.

The BGA arrangement 700 may include a WLP 710 analogous to the WLP layer 510 depicted in FIG. 5 and a plurality of solder balls analogous to the solder balls 170, 270, 530 depicted in FIGS. 1-2 and 5, respectively. The LGA arrangement 701 may include a WLP (not shown) analogous to the WLP layer 510 depicted in FIG. 5, a mold 740 analogous to the molds 380, 480, 540, 640 depicted in FIGS. 3-6, and a plurality of array pads analogous to one or more of the array pads 651, 652, 653, 654 depicted in FIG. 6.

As will be understood from FIG. 7, the solder balls in the BGA arrangement 700 may be arranged in a grid. For example, a solder ball 730 may be disposed such that it complements a particular PCB contact on a complementary PCB. The array pads in the LGA arrangement 701 may also be disposed such that they complement a particular PCB contact on a complementary PCB. For example, an array pad 750 may be disposed such that it complements the same PCB contact as the solder ball 730. However, the array pad 750 may have certain advantages over the solder ball 730, as discussed elsewhere in the present application. For example, the array pad 750 may have greater surface area than the solder ball 730 and/or may be made of different material, thereby permitting greater current flow and/or heat transfer from the WLP 710 to the PCB (or vice-versa).

To further improve current flow and/or heat transfer, multiple solder balls may be replaced by a single array pad. In some implementations, an electrical signal traveling from the WLP to the PCB (or vice-versa) may be associated with a current that exceeds the maximum current of a single solder ball. Accordingly, a high-current electrical signal may be sent through a plurality of solder balls. For example, a solder ball 731-1 and a solder ball 731-2 may be adjacent to one another and arranged in a linear lengthwise fashion with respect to BGA arrangement 700. The high-current electrical signal may be sent through the solder ball 731-1 and the solder ball 731-2 to a pair of complementary PCB contacts on the PCB.

However, in the LGA arrangement 701, an array pad 751 may be provided as a substitute for the solder balls 731-1, 731-2. The array pad 751 may permit greater current flow and/or heat transfer than the solder balls 731-1, 731-2 while occupying the same amount of space. As described above, a single array pad such as the array pad 750 may have greater surface area than a single solder ball such as solder ball 730. However, as will be understood from FIG. 7, an array pad that spans two solder balls, such as the array pad 751, may include not only the surface area of two array pads, but also a surface area associated with the spacing between adjacent array pads. This eliminates need to balance current between multiple solder balls.

Although the array pad 751 may be provided as a substitute for solder balls arranged in a linear lengthwise fashion with respect to BGA arrangement 700 (such as the solder balls 731-1, 731-2), it will be understood that, due to the flexibility of the LGA arrangements 701, a single array pad may also be provided as a substitute for solder balls arranged in a linear widthwise fashion. For example, solder balls 733-1, 733-2 may be arranged in a linear widthwise fashion with respect to the BGA arrangement 700. However, in the LGA arrangement 701, an array pad 753 permitting greater current flow and/or heat transfer may be provided as a substitute for the solder balls 733-1, 733-2.

Although the array pads 751, 753 may be provided as substitutes for solder balls arranged in a linear fashion with respect to BGA arrangement 700 (such as the solder balls 731-1, 731-2, 733-1, 733-2), it will be understood that, due to the flexibility of the LGA arrangements 701, a single array pad may also be provided as a substitute for solder balls arranged in an asymmetrical or non-linear fashion. For example, the solder balls 735-1, 735-2, 735-3 may be arranged in an asymmetrical or non-linear fashion with respect to the BGA arrangement 700. However, in the LGA arrangement 701, an array pad 755 permitting greater current flow and/or heat transfer may be provided as a substitute for solder balls 735-1, 735-2, 735-3.

To further increase current flow and/or heat transfer from the WLP to the PCB (or vice-versa), larger array pads are possible. For example, an array pad 757 may be provided as a substitute for solder balls 737-1, 737-2, 737-3, 737-4. The array pad 757 may permit greater current flow and/or heat transfer than the solder balls 737-1, 737-2, 737-3, 737-4, while occupying the same amount of space. Similarly, an array pad 759 may be provided as a substitute for nine solder balls disposed within an outline 739 of FIG. 7. The array pad 759 may permit greater current flow and/or heat transfer than the solder balls disposed within outline 739, while occupying the same amount of space.

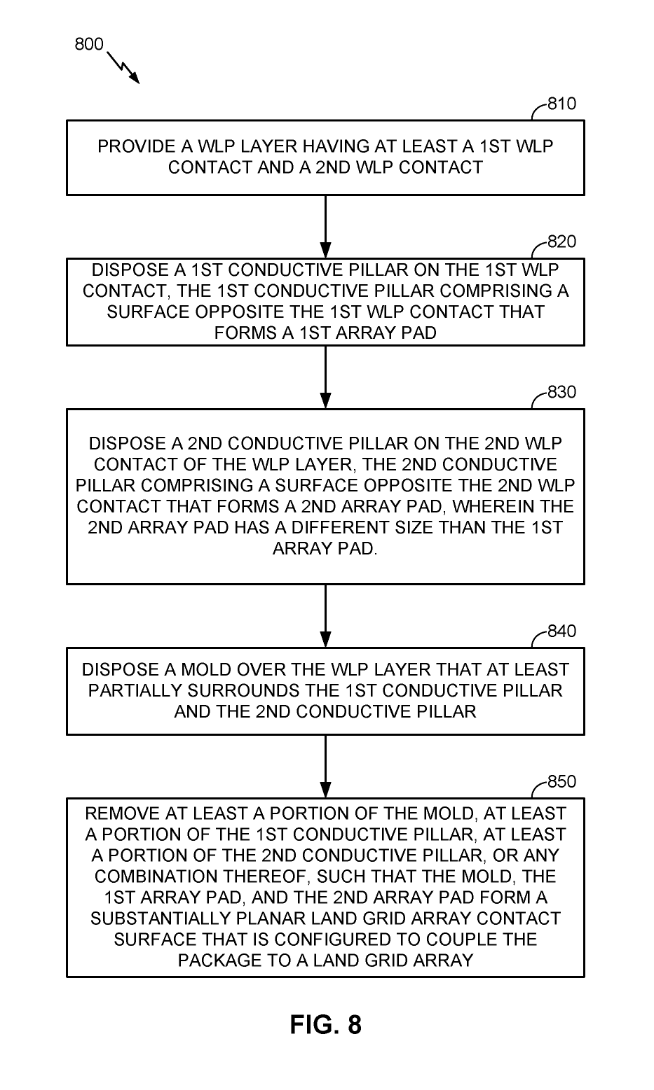

FIG. 8 generally illustrates a method 800 for fabricating, in accordance with aspects of the disclosure, a package.

At 810, the method 800 provides a WLP layer having at least a first WLP contact and a second WLP contact. The WLP layer may correspond to the elements 310, 312, 314, 320, 330, 340, 350 depicted in FIG. 3, the layers 410, 412, 414, 420, 422, 424, 430, 440, 450 depicted in FIG. 4, the WLP layer 510 depicted in FIG. 5, or any other WLP layer referred to in the present disclosure.

At 820, the method 800 disposes a first conductive pillar on the first WLP contact, the first conductive pillar comprising a surface opposite the first WLP contact that forms a first array pad. The first conductive pillar may be disposed using plating. The first conductive pillar may correspond to the conductive pillars 370, 470, 550 depicted in FIGS. 3-5 or any other conductive pillar referred to in the present disclosure. The first WLP contact may correspond to the UBMs 360, 460, 520 depicted in FIGS. 3-5 or any other WLP contact referred to in the present disclosure. The first array pad may correspond to any of the array pads depicted in FIG. 6, for example, the first array pad 651, the top surface of any of the conductive pillars 370, 470, 550 depicted in FIGS. 3-5, or any other array pad referred to in the present disclosure.

At 830, the method 800 disposes a second conductive pillar on the second WLP contact, the second conductive pillar comprising a surface opposite the second WLP contact that forms a second array pad, wherein the second array pad has a different size than the first array pad. The second conductive pillar may be disposed using plating. The second conductive pillar may correspond to the conductive pillars 370, 470, 550 depicted in FIGS. 3-5 or any other conductive pillar referred to in the present disclosure. The second WLP contact may correspond to the UBMs 360, 460, 520 depicted in FIGS. 3-5 or any other WLP contact referred to in the present disclosure. The first array pad and the second array pad having a different size than the first array pad, as referred to in the method 800, may correspond to any of the differently-sized array pads depicted in, for example, FIG. 6. The LGA arrangement may correspond to the LGA arrangement 600 depicted in FIG. 6, the LGA arrangement 701 depicted in FIG. 7, or any other LGA arrangement referred to in the present disclosure.

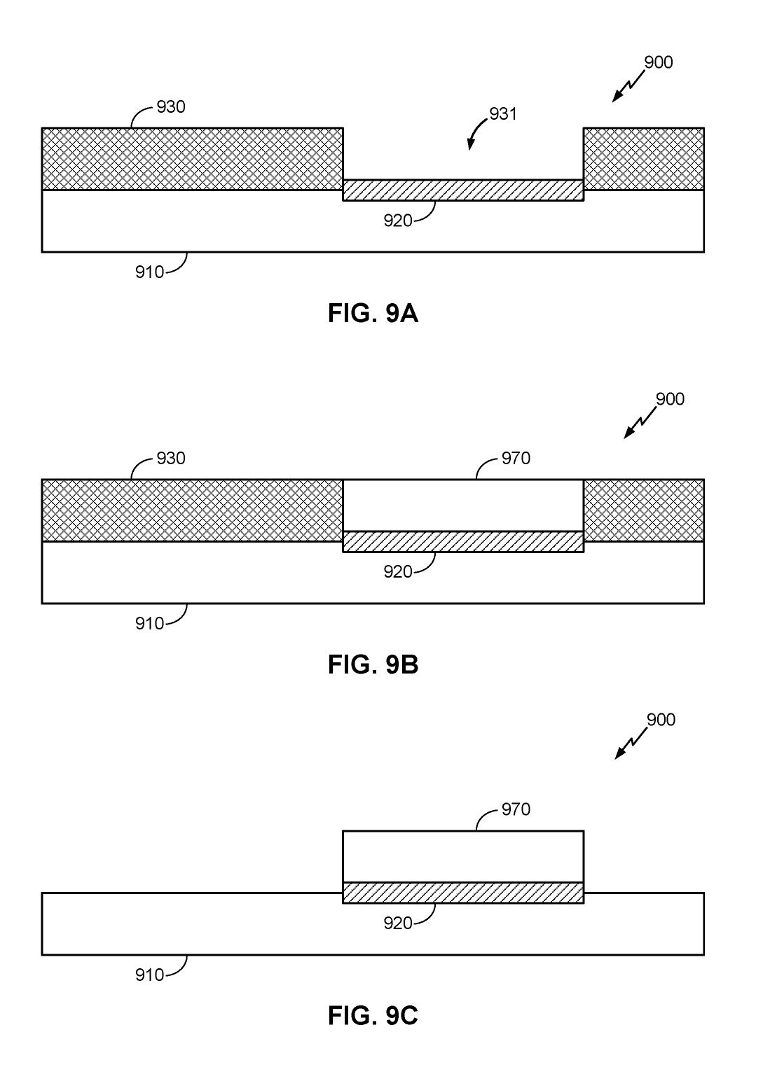

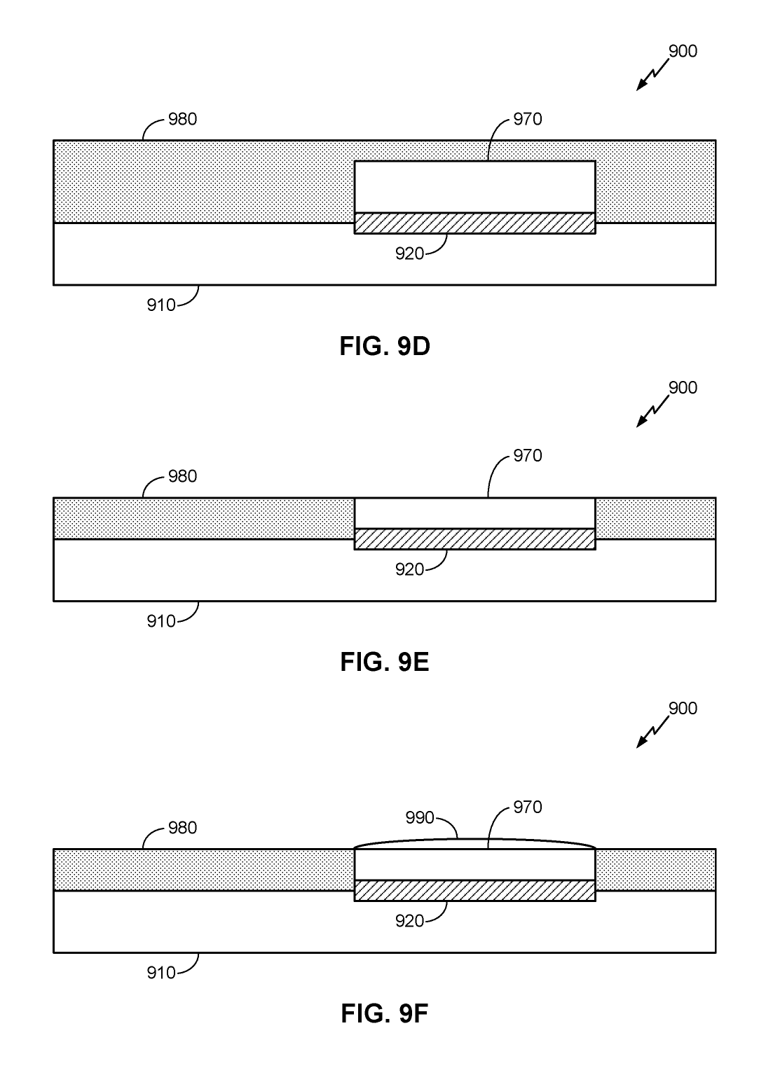

At 840, the method 800 disposes a mold over the WLP layer that at least partially surrounds the first conductive pillar and the second conductive pillar. The mold may refer to the mold 980, as will be described in greater detail below with respect to FIGS. 9A-9F.

At 850, the method 800 removes at least a portion of the mold, at least a portion of the first conductive pillar, at least a portion of the second conductive pillar, or any combination thereof, such that the mold, the first array pad, and the second array pad form a substantially planar land grid array contact surface that is configured to couple the package to a land grid array.

FIGS. 9A-9F generally illustrate a package 900 in various stages of fabrication in accordance with aspects of the disclosure.

FIG. 9A generally illustrates the package 900 in a first stage of fabrication. In particular, FIG. 9A depicts a WLP layer 910, a WLP contact 920, and a mask 930. In some implementations, the WLP contact 920 may be a UBM similar to the UBMs 160, 260, 360, 460, 520. Additionally or alternatively, the WLP contact 920 may be an exposed conductor or land array pad of the WLP layer 910. As will be understood from FIG. 9A, the mask 930 covers at least a portion of the WLP layer 910. However, the mask 930 has a spacing 931 and therefore does not cover at least a portion of the WLP contact 920.

FIG. 9B generally illustrates the package 900 in a second stage of fabrication. In particular, a conductive pillar 970 is disposed within the spacing 931 of the mask 930 and disposed on at least a portion of the WLP contact 920. The conductive pillar 970 may include any suitable conductive material, for example, copper or solder. The conductive pillar 970 may be disposed within the spacing 931 using any suitable method, for example, plating. Accordingly, the conductive pillar 970 may include plated copper, plated solder, or any combination thereof.

FIG. 9C generally illustrates the package 900 in a third stage of fabrication. In particular, the mask 930 has been removed, leaving the conductive pillar 970 disposed on the WLP contact 920.

FIG. 9D generally illustrates the package 900 in a fourth stage of fabrication. In particular, a mold 980 may be disposed on at least a portion of the WLP layer 910 and/or at least a portion of the conductive pillar 970. The mold 980 may include any suitable material, for example, epoxy, resin, mold compound, etc. As depicted in FIG. 9D, the conductive pillar 970 may be wholly embedded in the mold 980, however, it will be understood that the conductive pillar 970 may be, for example, partially embedded in the mold 980.

FIG. 9E generally illustrates the package 900 in a fifth stage of fabrication. In particular, a portion of the conductive pillar 970 and/or a portion of the mold 980 have been removed so as to expose at least part of the conductive pillar 970. The exposed portion of the conductive pillar 970 may constitute an array pad, and the conductive pillar 970 may couple the array pad to the WLP contact 920. The removing may be performed using any suitable method, for example, back grinding. As depicted in FIG. 9E, the removing may be performed such that the external surfaces of the conductive pillar 970 and the mold 980 lie in a single plane.

FIG. 9F generally illustrates the package 900 in an optional sixth stage of fabrication. In particular, solder 990 has been added to the external surface of the conductive pillar 970. Depending on the type of material included in the conductive pillar 970, the solder 990 may facilitate mounting of the package 900 to a PCB. For example, if the conductive pillar 970 includes plated copper, then the solder 990 may facilitate mounting of the package 900 to a PCB. However, as another example, if the conductive pillar 970 includes plated solder, then the solder 990 may be omitted.

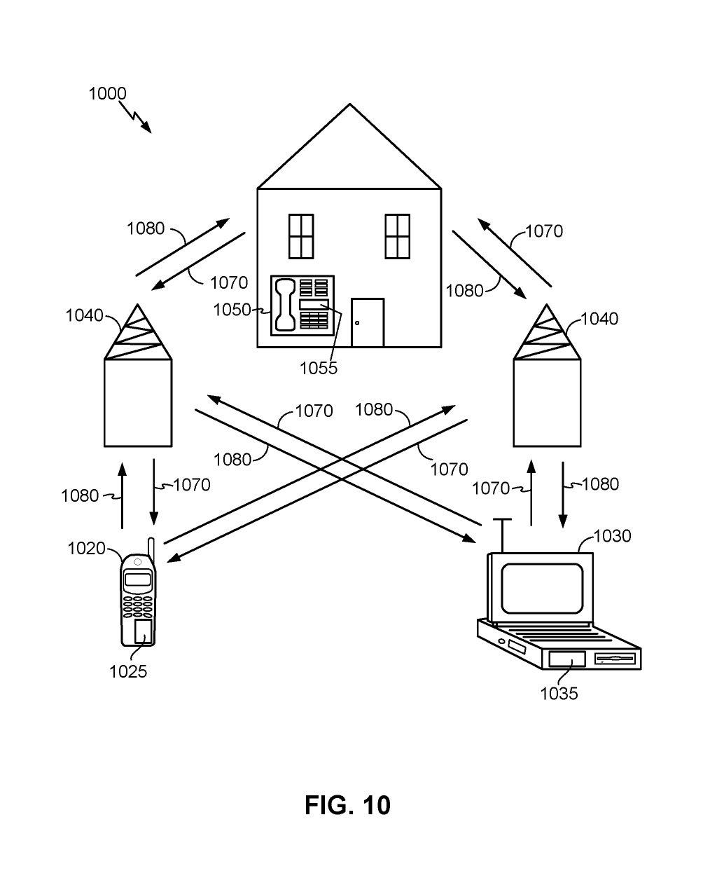

FIG. 10 is a block diagram showing an exemplary wireless communication system 1000 in which aspects of the disclosure may be advantageously employed. For purposes of illustration, FIG. 10 shows three remote units 1020, 1030, and 1050 and two base stations 1040. It will be recognized that wireless communication systems may have many more remote units and base stations. Remote units 1020, 1030, and 1050 include IC devices 1025, 1035 and 1055, as disclosed below. It will be recognized that any device containing an IC may also include semiconductor components having the disclosed features and/or components manufactured by the processes disclosed here, including the base stations, switching devices, and network equipment. FIG. 10 shows forward link signals 1080 from the base stations 1040 to the remote units 1020, 1030, and 1050 and reverse link signals 1070 from the remote units 1020, 1030, and 1050 to base stations 1040.

In FIG. 10, the remote unit 1020 is shown as a mobile telephone, the remote unit 1030 is shown as a portable computer, and the remote unit 1050 is shown as a fixed location remote unit in a wireless local loop system. For example, remote units may be a device such as a set top box, a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle. Although FIG. 10 illustrates remote units according to the teachings of the disclosure, the disclosure is not limited to these exemplary illustrated units. The disclosure may be suitably employed in any device which includes semiconductor components, as described below.

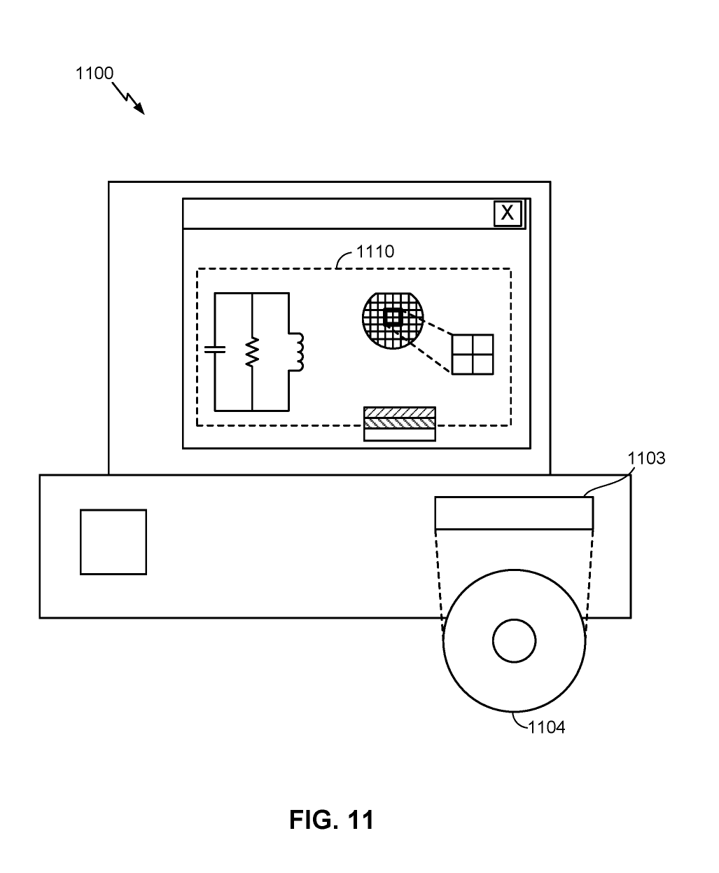

FIG. 11 is a block diagram illustrating a design workstation for circuit, layout, and design of a semiconductor part as disclosed herein. A design workstation 1100 may include a hard disk containing operating system software, support files, and design software such as Cadence or OrCAD. The design workstation 1100 also includes a display to facilitate design of a semiconductor part 1110 that may include a circuit and semiconductor dies. A storage medium 1104 is provided for tangibly storing the semiconductor part 1110. The semiconductor part 1110 may be stored on the storage medium 1104 in a file format such as GDSII or GERBER. The storage medium 1104 may be a CD-ROM, DVD, hard disk, flash memory, or other appropriate device. Furthermore, the design workstation 1100 includes a drive apparatus 1103 for accepting input from or writing output to the storage medium 1104.

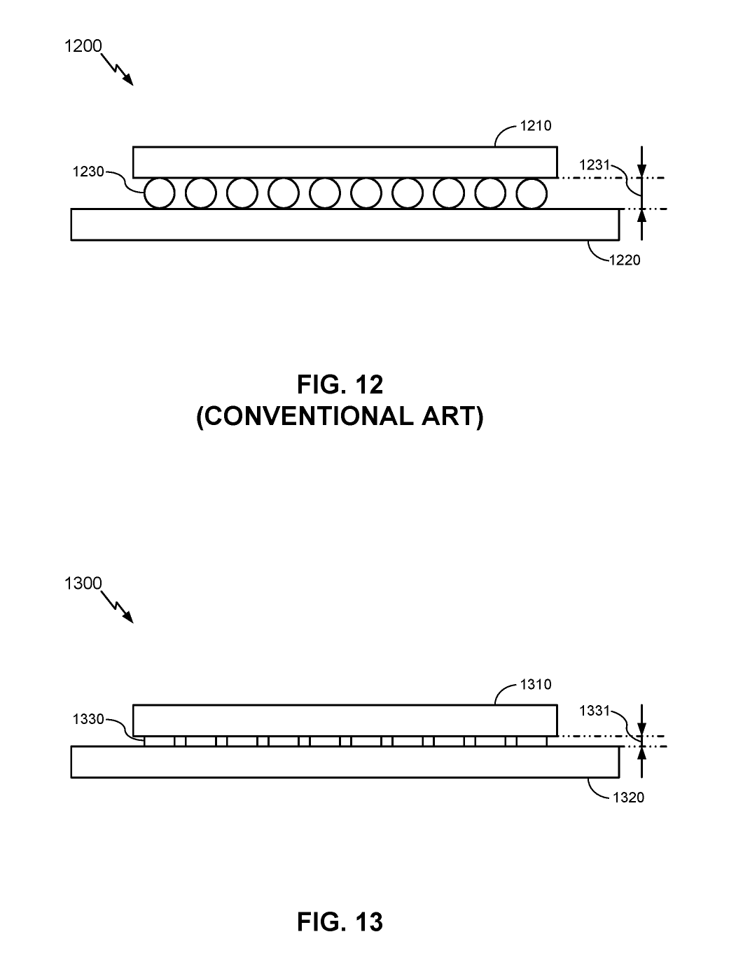

FIG. 12 generally illustrates a integrated circuit package 1200 having a conventional BGA arrangement. FIG. 13 generally illustrates a integrated circuit package 1300 having (in accordance with aspects of the disclosure) an LGA arrangement. The integrated circuit package 1200 may be analogous in some respects to the wafer-level packages 100, 200 depicted in FIGS. 1-2, whereas the integrated circuit package 1300 may be analogous in some respects to the packages 300, 400 depicted in FIGS. 3-4.

The integrated circuit package 1200 and the integrated circuit package 1300 may some analogous components. For example, the integrated circuit package 1200 may have a package 1210 and a printed circuit board 1220. The integrated circuit package 1300 may have a package 1310 analogous to the package 1210 and a printed circuit board 1320 analogous to the printed circuit boards 1220. The packages 1210, 1310 and the printed circuit boards 1220, 1320 may each have a substantially ‘flat’ shape. A component with a flat shape may have a component length and a component width that greatly exceed the component height, for example, the component length and a component width may be ten times, one hundred times, or one thousand times the component height.

The integrated circuit package 1200 includes a plurality of solder balls 1230 similar to the solder balls 170, 270 depicted in FIGS. 1-2. After the package 1210 is mounted to the printed circuit board 1220, the overall height of the integrated circuit package 1200 may depend on the height of the package 1210, the height of the printed circuit board 1220, and the height of the solder balls 1230. FIG. 12 depicts the solder ball height 1231.

By contrast, the integrated circuit package 1300 includes a plurality of conductive pillars 1330 similar to the conductive pillars 370, 470 depicted in FIGS. 3-4. Accordingly, the overall height of the integrated circuit package 1300 may depend on the height of the package 1310, the height of the printed circuit board 1320, and the height of the conductive pillars 1330. FIG. 13 depicts the conductive pillar height 1331.

As will be understood from FIGS. 12-13, the overall height of the integrated circuit package 1300, which includes the conductive pillar height 1331, may be much smaller than the overall height of the integrated circuit package 1200, which includes the solder ball height 1231. Another advantage of the integrated circuit package 1300 is the flexibility with which the conductive pillar height 1331 may be selected. For example, in some implementations, the package 1310 may include a component associated with a keepout area or keepout zone. The component may be associated with electrical and/or magnetic fields (for example, an inductor) that must be displaced from the printed circuit board 1320 by a keepout distance. As can be understood from FIG. 13, the conductive pillar height 1331 of the conductive pillars 370 may be selected such that the component is displaced from the printed circuit board 1320 by at least the keepout distance. Accordingly, as the position or characteristics of the component changes (as may occur during circuit design), the conductive pillar height 1331 may be flexibly selected such that the keepout distance is observed but the conductive pillar height 1331 (and the overall height of the integrated circuit package 1300) is otherwise minimized.

Data recorded on the storage medium 1104 may specify logic circuit configurations, pattern data for photolithography masks, or mask pattern data for serial write tools such as electron beam lithography. Providing data on the storage medium 1104 facilitates the design of the semiconductor part 1110 by decreasing the number of processes for designing circuits and semiconductor dies.

The foregoing description may have references to discrete elements or properties, such as a capacitor, capacitive, a resistor, resistive, an inductor, inductive, conductor, conductive and the like. However, it will be appreciated that the various aspects disclosed herein are not limited to specific elements and that various components, elements or portions of components or elements may be used to achieve the functionality of one or more discrete elements or properties. For example, a capacitive component or capacitive element may be a discrete device or may be formed by a specific arrangement of conductive traces separated by a dielectric material or combinations thereof. Likewise, an inductive component or inductive element may be a discrete device or may be formed by a specific arrangement of conductive traces and materials (e.g., air core, magnetic, paramagnetic, etc.) or combinations thereof. Similarly, a resistive component or resistive element may be a discrete device or may be formed by a semiconductor material, insulating material, adjusting the length and/or cross-sectional area of conductive traces, or combinations thereof. Moreover, a specific arrangement of conductive traces and materials may provide one or more resistive, capacitive or inductive functions. Accordingly, it will be appreciated that the various components or elements disclosed herein are not limited to the specific aspects and or arrangements detailed, which are provided merely as illustrative examples.

While the foregoing disclosure shows illustrative aspects of the disclosure, it should be noted that various changes and modifications could be made herein without departing from the scope of the invention as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

1. A package comprising:
a wafer-level package (WLP) layer comprising a first WLP contact and a second WLP contact;
a first conductive pillar disposed on the first WLP contact, the first conductive pillar comprising a surface opposite the first WLP contact that forms a first array pad;
a second conductive pillar disposed on the second WLP contact, the second conductive pillar comprising a surface opposite the second WLP contact that forms a second array pad, wherein the second array pad has a different size than the first array pad; and
a mold over the WLP layer and at least partially surrounding the first conductive pillar and the second conductive pillar, wherein the mold, the first array pad, and the second array pad form a substantially planar land grid array contact surface that is configured to couple the package to a land grid array.

2. The package of claim 1, wherein the first conductive pillar includes one or more of copper, solder, or any combination thereof.

3. The package of claim 1, wherein the first WLP contact comprises a first under-bump metallization UBM.

4. The package of claim 1, wherein the first WLP contact comprises a conductive trace within the WLP layer.

5. The package of claim 1, wherein the WLP layer is a fan-out WLP layer.

6. The package of claim 1, wherein the mold, the first conductive pillar, the second conductive pillar, or any combination thereof has a land grid array component height configured to provide a keepout distance between a component in the WLP layer and the substantially planar land grid array contact surface.

7. The package of claim 6, wherein the component is an inductor.

8. The package of claim 1, wherein the substantially planar land grid array contact surface is configured to be coupled to a printed circuit board.

9. The device of claim 1, wherein the integrated device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle.

10. A method of fabricating a package, comprising:
providing a wafer-level package (WLP) layer comprising a first WLP contact and a second WLP contact;
disposing a first conductive pillar on the first WLP contact, the first conductive pillar comprising a surface opposite the first WLP contact that forms a first array pad;
disposing a second conductive pillar on the second WLP contact, the second conductive pillar comprising a surface opposite the second WLP contact that forms a second array pad, wherein the second array pad has a different size than the first array pad;
disposing a mold over the WLP layer that at least partially surrounds the first conductive pillar and the second conductive pillar; and
removing at least a portion of the mold, at least a portion of the first conductive pillar, at least a portion of the second conductive pillar, or any combination thereof, such that the mold, the first array pad, and the second array pad form a substantially planar land grid array contact surface that is configured to couple the package to a land grid array.

11. The method of claim 10, wherein disposing the first conductive pillar comprises plating the first conductive pillar using copper, plating the first conductive pillar using solder, or any combination thereof.

12. The method of claim 10, wherein the first WLP contact comprises a first under-bump metallization.

13. The method of claim 10, wherein the first WLP contact comprises a conductive trace within the WLP layer.

14. The method of claim 10, wherein the WLP layer is a fan-out WLP layer.

15. The method of claim 10, removing at least a portion of the mold, at least a portion of the first conductive pillar, at least a portion of the second conductive pillar, or any combination thereof comprises maintaining a land grid array component height configured to provide a keepout distance between a component in the WLP layer and the substantially planar land grid array contact surface.

16. The method of claim 15, wherein the component is an inductor.

17. The method of claim 10, wherein the substantially planar land grid array contact surface is configured to be coupled to a printed circuit board.

18. An apparatus comprising:
means for processing comprising first means for contacting and second means for contacting;
first means for conducting disposed on first means for contacting, first means for conducting comprising a surface opposite first means for contacting that forms a first array pad;
second means for conducting disposed on second means for contacting, second means for conducting comprising a surface opposite second means for contacting that forms a second array pad, wherein the second array pad has a different size than the first array pad; and
means for supporting disposed over the means for processing and at least partially surrounding first means for conducting and second means for conducting, wherein the means for supporting, the first array pad, and the second array pad form a substantially planar land grid array contact surface that is configured to couple the package to a land grid array.

19. The apparatus of claim 18, wherein first means for conducting includes one or more of copper, solder, or any combination thereof.

20. The apparatus of claim 18, wherein first means for contacting comprises a first under-bump metallization UBM.

21. The apparatus of claim 18, wherein first means for contacting comprises a conductive trace within the means for processing.

22. The apparatus of claim 18, wherein means for processing is a fan-out WLP layer.

23. The apparatus of claim 18, wherein the means for supporting, first means for conducting, second means for conducting, or any combination thereof has a land grid array component height configured to provide a keepout distance between a component in means for processing and the substantially planar land grid array contact surface.

24. The apparatus of claim 23, wherein the component is an inductor.

25. The apparatus of claim 18, wherein the substantially planar land grid array contact surface is configured to be coupled to a printed circuit board.

26. The device of claim 18, wherein the integrated device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle.
